(19) United States
(12) Patent Application Publication
(10) Pub. No.: US 2017/0139247 A1
(43) Pub. Date: May 18, 2017

(54) Thin Film Transistor Array Substrate, Manufacturing for the Same, and Liquid Crystal Display Panel Having the Same

(71) Applicant: Shenzhen China Star Optoelectronics Technology Co. Ltd., Shenzhen, Guangdong (CN)

(72) Inventors: Yue WU, Shenzhen, Guangdong (CN); Weina YONG, Shenzhen, Guangdong (CN); Shan LI, Shenzhen, Guangdong (CN)

(73) Assignee: Shenzhen China Star Optoelectronics Technology Co. Ltd., Shenzhen, Guangdong (CN)

(21) Appl. No.: 14/773,410

(22) PCT Filed: Aug. 13, 2015
(86) PCT No.: PCT/CN2015/086815

§ 371 Date: Sep. 8, 2015

(30) Foreign Application Priority Data
Aug. 6, 2015 (CN) 20151047526.9

(51) Int. Cl. G02F 1/1368; H01L 29/423; H01L 29/786; H01L 21/28

(52) U.S. Cl. CPC G02F 1/1368; H01L 21/28158; H01L 29/42384; H01L 29/78696; H01L 2029/42388

(57) ABSTRACT

A thin film transistor array substrate includes a glass substrate and a plurality of TFTs thereon. Each TFT includes a gate formed on the glass substrate, a gate insulating layer covering the gate, an active layer formed on the gate insulating layer, a source on the active layer, and a drain on the active layer. A gap is between the source and the drain in a first direction. An area of the active layer that matches the gap is a channel. A plurality of protrusions and recesses on a coarse surface of the gate insulating layer face the active layer, at least within the area corresponding to the channel. The active layer fits with the gate insulting layer. The present invention also proposes a method for manufacturing the thin film transistor array substrate and a liquid crystal display panel having the thin film transistor array substrate.

### BACKGROUND OF THE INVENTION

1. Field of the Invention

The present invention relates to liquid crystal display technology field, more particularly to a thin film transistor array substrate and manufacturing for the same, as well as a liquid crystal display panel having the same.

2. Description of the Prior Art

A liquid crystal display (LCD) has such merits of thinness, lightness, power saving, and low radiation as to be applied in notebook computers, mobile phones, electronic dictionaries and other electronic display devices. As per the LCD technology having been developing, so changes the environment in which the electronic display devices are used. They are more often used outdoors. Demand on visual effects is rising, so a LCD device of greater lightness is expected. The LCD panel is a main component of the LCD.

A common liquid crystal display panel comprises a thin film transistor array substrate, a color filter substrate, and a liquid crystal layer therebetween. A thin film transistor array substrate comprises a glass substrate and a thin film transistor arrayed on the glass substrate. Please refer to FIG. 1 showing a cross-sectional view of a thin film transistor, which comprises the following: a gate 2 formed on a glass substrate 1, a gate insulating layer 3 covering the gate 2, an active layer 4 formed on the gate insulating layer 3, and a source 5 as well as a drain 6 formed on the active layer 4. There is a gap between the source 5 and the drain 6, and the area of the active layer 4 that matches the gap is a channel 4a . Please refer to FIG. 2 showing a top view of the thin film transistor, in which only the gate 2, the active layer 4, the source 5, and the drain 6 are shown. The channel 4a has a length L and a width W.

The design of a thin film transistor array substrate asks for large on-state current and small off-state current. One way to enlarge on-state current is to increase the width to length ratio (W/L) of the channel, either to increase the width W or to decrease the length L. In order to ensure display resolution, the pixel area has to be as small as possible, with aperture ratio being as high as possible, so the thin film transistor and its peripheral circuit are limited to a certain size, meaning the channel width W has to be limited too, leaving the only way to increase the W/L ratio to be decreasing the length L. However, when L is decreased to a certain level, current leakage as well as channel break through will ensue, making the thin film transistor unable to work.

### SUMMARY OF THE INVENTION

In view of the weakness of conventional technology, the present invention provides a thin film transistor array substrate and manufacturing for the same in order to increase the W/L ratio of the channel, so as to enlarge on-state current of the thin film transistor, enhancing the driving ability of the thin film transistor.

According to the present invention, a thin film transistor (TFT) array substrate comprises a glass substrate and a plurality of TFTs thereon. Each TFT comprises: a gate formed on the glass substrate, a gate insulating layer covering the gate, an active layer formed on the gate insulating layer, a source on the active layer, and a drain on the active layer. A gap is between the source and the drain in a first direction. An area of the active layer that matches the gap is a channel. A plurality of protrusions and recesses on a coarse surface of the gate insulating layer face the active layer, at least within the area corresponding to the channel. The active layer fits with the gate insulting layer.

Furthermore, each of the plurality of protrusions extends along a first direction, and the plurality of protrusions align in a sequence along a second direction perpendicular to the first direction.

Furthermore, each of the plurality of protrusions straightly or windingly extends along the first direction.

Furthermore, each of the plurality of protrusions is shaped as a semicircle or a shape close to a semicircle in a cross-sectional view along the second direction.

Furthermore, the plurality of protrusions are equally-spaced along the second direction, and the coarse surface with the plurality of recesses along the second direction is wave-shaped in a cross sectional view.

Furthermore, the plurality of protrusions in a cross sectional view is shaped as triangles.

Furthermore, the plurality of protrusions are equally spaced and align in a sequence along the second direction, while the recesses on the coarse surface, aligning in a sequence along the second direction, are saw-shaped.

Furthermore, the TFT substrate further comprises scan lines as well as data lines on the glass substrate. Pixel areas are surrounded by the scan lines and the data lines. The TFT and a pixel electrode is within the pixel area, the pixel electrode is electrically connected to the source or the drain of the TFT.

According to the present invention, a method of manufacturing a thin film transistor (TFT) substrate comprises: (S101) providing a glass substrate and forming a gate on the glass substrate; (S102) forming a gate insulating layer covering the gate; (S103) forming a coarse surface on the gate insulting layer, with a plurality of protrusions and a plurality of recesses, by embossing or etching processes; (S104) forming an active layer on the gate insulting layer, where a surface of the active layer fits the gate insulting layer; and (S105) forming a source and drain on the active layer.

According to the present invention, a liquid crystal display (LCD) panel comprises an array substrate as mentioned above, a color filter substrate, and liquid crystal layer therebetween.

In contrast to prior art, the present invention provides a thin film transistor in which a junction between the active layer and the gate insulating layer corresponding to the channel is a coarse surface with protrusions and recesses. The coarse junction between the active layer and the gate insulating layer increases the width of the channel (i.e. the width of the straightened surface of the channel), so the W/L ratio of the channel increases, so as to enlarge on-state current and enhance the driving ability of the thin film transistor. In addition, since the length and width in vertical direction (i.e. the vertical distance across two sides of the channel in the width direction) of the channel remain, the aperture ratio does not change despite the increase of the W/L ratio of the channel.

### BRIEF DESCRIPTION OF THE DRAWINGS

FIG. 1 shows a cross sectional view of a conventional thin film transistor.

FIG. 2 shows a top view of the thin film transistor as shown in FIG. 1.

FIG. 3 shows a schematic diagram of a liquid crystal display panel according to a preferred embodiment of the present invention.

FIG. 4 shows a schematic diagram of a TFT array substrate according to a preferred embodiment of the present invention.

FIG. 5 shows a schematic diagram of a color filter substrate according to a preferred embodiment of the present invention.

FIG. 6 is a top view of a thin film transistor according to a preferred embodiment of the present invention.

FIG. 7 is a cross sectional view of the thin film transistor along a line AA shown in FIG. 6.

FIG. 8 is a cross sectional view of the thin film transistor along a line BB shown in FIG. 6.

FIG. 9 is a top view of a gate insulating layer according to a preferred embodiment of the present invention.

FIG. 10 is a top view of a gate insulating layer according to another preferred embodiment of the present invention.

FIG. 11 is a side view of a gate insulating layer according to a preferred embodiment of the present invention.

FIG. 12 is a side view of a gate insulating layer according to another preferred embodiment of the present invention.

FIG. 13 is a flowchart of a method of manufacturing a TFT substrate according to a preferred embodiment of the present invention.

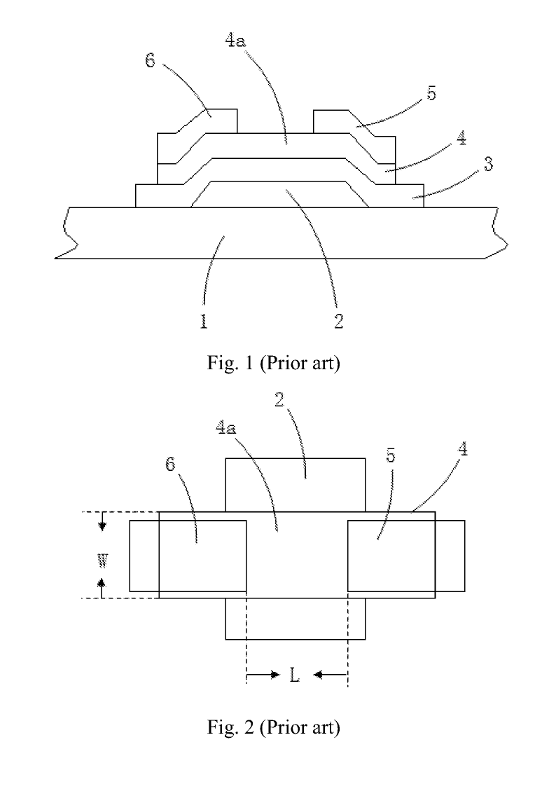

### DETAILED DESCRIPTION OF THE PREFERRED EMBODIMENTS

For better understanding embodiments of the present invention, the following detailed description taken in conjunction with the accompanying drawings is provided. Apparently, the accompanying drawings are merely for some of the embodiments of the present invention. Any ordinarily skilled person in the technical field of the present invention could still obtain other accompanying drawings without use laborious invention based on the present accompanying drawings.

The accompanying drawings illustrate embodiments of the invention and, together with the description, serve to explain the principles of the invention. The irrelevant structure or/and steps are omitted.

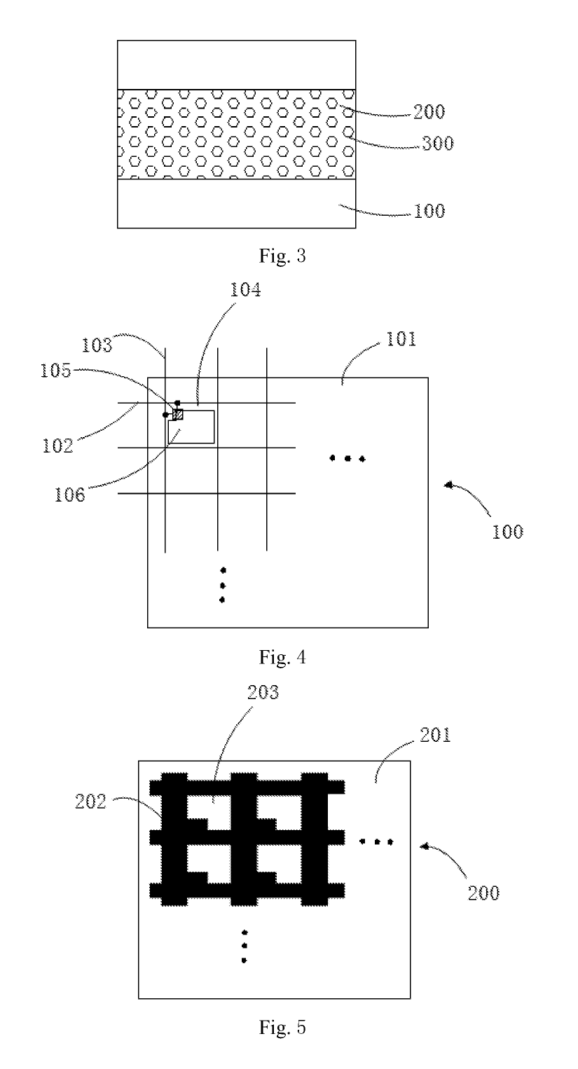

Please refer to FIG. 3 showing a liquid crystal display panel according to a preferred embodiment of the present invention. The liquid crystal display panel comprises a thin film transistor array substrate 100, a color filter substrate 200, and a liquid crystal layer 300 therebetween. As shown in FIG. 4, the thin film transistor array substrate 100 comprises a glass substrate 101, scan lines 102 as well as data lines 103 set on the glass substrate 101, and pixel areas 104 surrounded by the crossing scan lines 102 and data lines 103. In each of the pixel areas 104, a thin film transistor 105 and a pixel electrode 106 are set. The thin film transistor 105 is electrically connected to the pixel electrode 106. Also, the thin film transistor 105 is electrically connected to the relative scan line 102 and data line 103. As shown in FIG. 5, the color filter substrate 200 comprises a glass substrate 201 and a black matrix 202 as well as color photoresist units 203 formed on the glass substrate 201. The color photoresist units 203 comprise red photoresists, green photoresists, and blue photoresists. Each of the color photoresist units 203 and the surrounding black matrix 202 match one pixel area 104 on the thin film transistor array substrate 100.

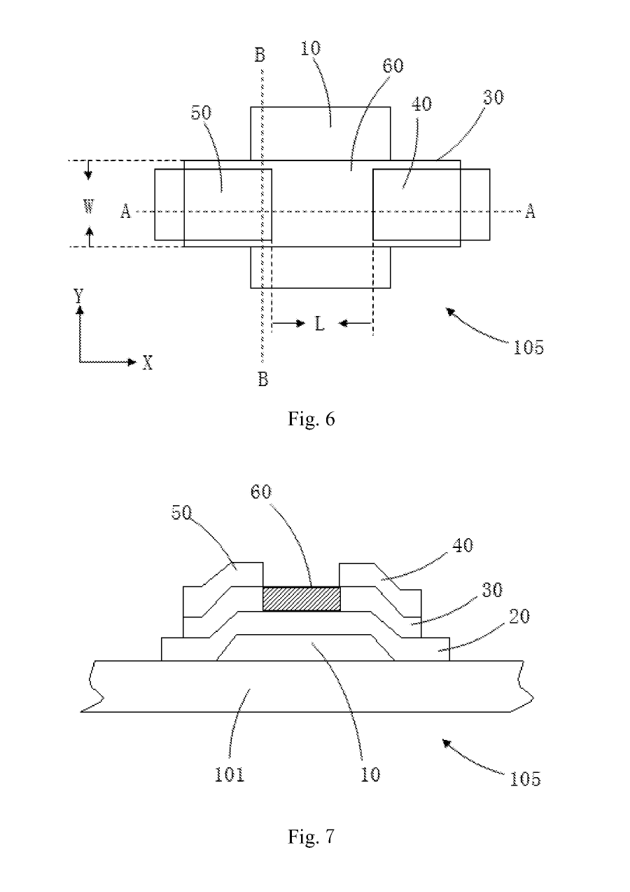

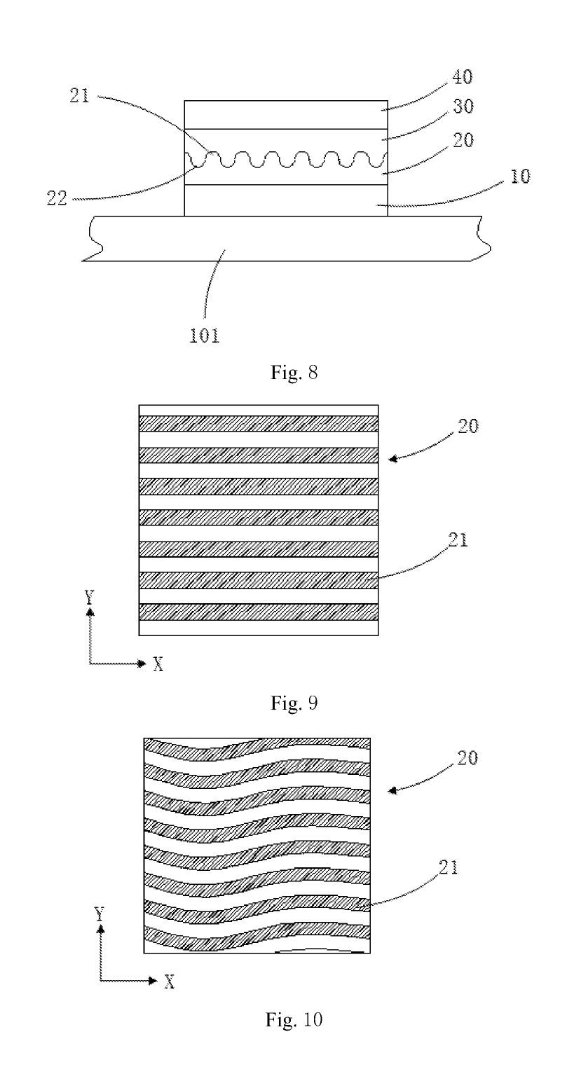

Please refer to FIG. 6 to FIG. 8. FIG. 6 is a top view of the preferred embodiment of the thin film transistor of the present invention. FIG. 7 is a cross-sectional view cut from line AA of the thin film transistor from FIG. 6. FIG. 8 is a cross-sectional view cut from line BB of the thin film transistor from FIG. 6. The thin film transistor 105 in the preferred embodiment comprises the following: a gate 10 formed on the glass substrate 101, a gate insulating layer 20 covering the gate 10, an active layer 30 formed on the gate insulating layer 20, and a source 40 as well as a drain 50 formed on the active layer 30. There is a gap between the source 40 and the drain 50 in the first direction (i.e. the X direction in FIG. 6), and the area of the active layer 30 that matches the gap is a channel 60. Combined with FIG. 4, the gate 10 of the thin film transistor 105 is electrically connected to the relative scan line 102. And if the source 40 is electrically connected to the relative data line 103, then the drain 50 is electrically connected to the pixel electrode 106. While if the source 40 is electrically connected to the pixel electrode 106, then the drain 50 is electrically connected to the relative data line 103. The channel 60 has a length L in the first direction, and a vertical width W in the second direction (i.e. the Y direction in FIG. 6). The vertical width W refers to the vertical distance across two sides of the channel 60 in the second direction.

Furthermore, as shown in FIG. 8, a plurality of protrusions 21 and recesses 22 on the coarse surface of the gate insulating layer 20 face the active layer 30, at least within the area corresponding to the channel 60. The active layer 30 fits with the gate insulting layer 20, that is, the active layer 30 also comprises a coarse surface with protrusions and recesses fitting the recesses 22 and the protrusions 21 of the gate insulating layer 20.

As shown in FIG. 9, the plurality of protrusions 21 of the gate insulating layer 20 extends along the first direction (X direction), and aligns in a sequence along the second direction (Y direction). Furthermore, the plurality of protrusions 21 extends straightly along the first direction as shown in FIG. 9, or the plurality of protrusions 21 extends windingly along the first direction, as shown in FIG. 10.

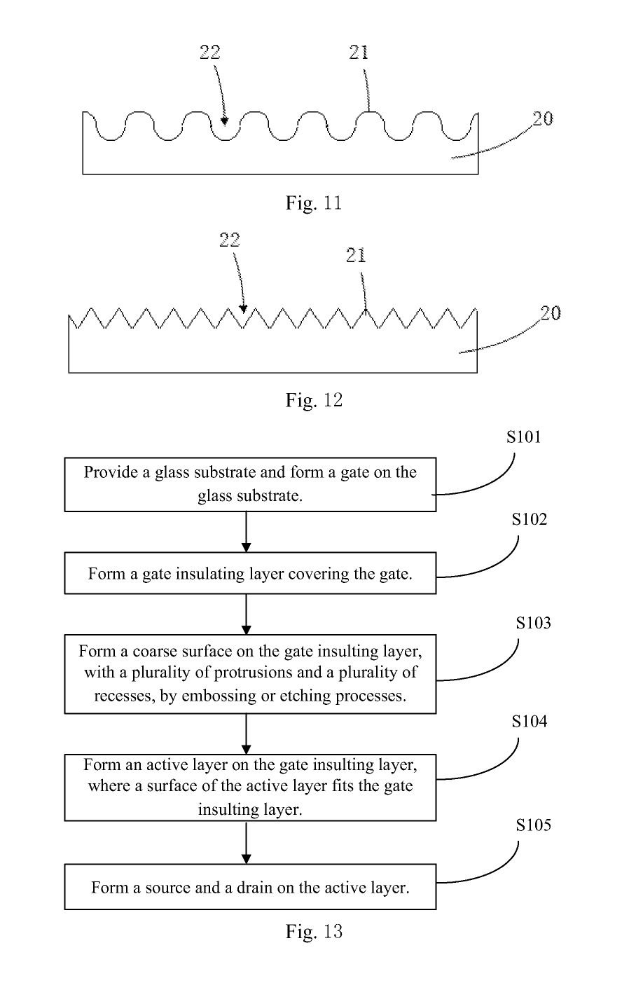

Please refer to FIG. 11. Each of the protrusions 21 is shaped as a semicircle or a shape close to a semicircle in a cross-sectional view along the second direction. In addition, the protrusions 21 are equally-spaced along the second direction. The coarse surface with the plurality of recesses 22 along the second direction is wave-shaped in a cross sectional view. In another embodiment, the protrusions 21 are unequally-spaced along the second direction.

Furthermore, the protrusions 21 in a cross sectional view can be shaped as other shapes, e.g. triangles as suggested in FIG. 12. The protrusions 21 are equally spaced and align in a sequence along a second direction. The recesses 22 on the coarse surface, aligning in a sequence along the second direction, are saw-shaped.

The thin film transistor 105 in which a junction between the active layer 30 and the gate insulating layer 20 corresponding to the channel 60 is a coarse surface with protrusions 21 and recesses 22. The coarse junction between the active layer 30 and the gate insulating layer 20 increases the effective width of the channel 60 (i.e. the width of the straightened surface of the channel 60 is longer than the vertical width W of the channel 60), so the W/L ratio of the channel 60 increases, so as to enlarge on-state current and enhance the driving ability of the thin film transistor 105. In addition, since the length of the channel and width in vertical direction of the channel remain, the aperture ratio does not change despite the increase of the W/L ratio of the channel. In another aspect, upon keeping the W/L ratio of the channel unchanged, the present inventive TFT can reduce the width in vertical direction, thereby raising the aperture ratio.

Please refer to FIG. 13 illustrating a flowchart of a method of manufacturing the TFT substrate according to a preferred embodiment of the present invention. The method comprises:

S101: Provide a glass substrate and form a gate on the glass substrate.

S102: Form a gate insulating layer covering the gate.

S103: Form a coarse surface on the gate insulting layer, with a plurality of protrusions and a plurality of recesses, by embossing or etching processes.

S104: Form an active layer on the gate insulting layer, where a surface of the active layer fits the gate insulting layer.

S105: Form a source and a drain on the active layer.

The terms “a” or “an”, as used herein, are defined as one or more than one. The term “another”, as used herein, is defined as at least a second or more. The terms “including” and/or “having” as used herein, are defined as comprising. It should be noted that if it is described in the specification that one component is “connected,” “coupled” or “joined” to another component, a third component may be “connected,” “coupled,” and “joined” between the first and second components, although the first component may be directly connected, coupled or joined to the second component.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A thin film transistor (TFT) array substrate, comprising a glass substrate and a plurality of TFTs thereon, each TFT comprising: a gate formed on the glass substrate, a gate insulating layer covering the gate, an active layer formed on the gate insulating layer, a source on the active layer, and a drain on the active layer, wherein a gap is between the source and the drain in a first direction, an area of the active layer that matches the gap is a channel, and wherein a plurality of protrusions and recesses on a coarse surface of the gate insulating layer face the active layer, at least within the area corresponding to the channel, and the active layer fits with the gate insulting layer.

2. The TFT substrate of claim 1, wherein each of the plurality of protrusions extends along a first direction, and the plurality of protrusions align in a sequence along a second direction perpendicular to the first direction.

3. The TFT substrate of claim 2, wherein each of the plurality of protrusions straightly or windingly extends along the first direction.

4. The TFT substrate of claim 3, wherein each of the plurality of protrusions is shaped as a semicircle or a shape close to a semicircle in a cross-sectional view along the second direction.

5. The TFT substrate of claim 4, wherein the plurality of protrusions are equally-spaced along the second direction, and the coarse surface with the plurality of recesses along the second direction is wave-shaped in a cross sectional view.

6. The TFT substrate of claim 3, wherein the plurality of protrusions in a cross sectional view is shaped as triangles.

7. The TFT substrate of claim 6, wherein the plurality of protrusions are equally spaced and align in a sequence along the second direction, while the recesses on the coarse surface, aligning in a sequence along the second direction, are saw-shaped.

8. The TFT substrate of claim 1 further comprising scan lines as well as data lines on the glass substrate, wherein pixel areas surrounded by the scan lines and the data lines; the TFT and a pixel electrode is within the pixel area, the pixel electrode is electrically connected to the source or the drain of the TFT.

9. A method of manufacturing a thin film transistor (TFT) substrate, comprising:
(S101) providing a glass substrate and forming a gate on the glass substrate;
(S102) forming a gate insulating layer covering the gate;
(S103) forming a coarse surface on the gate insulting layer, with a plurality of protrusions and a plurality of recesses, by embossing or etching processes;
(S104) forming an active layer on the gate insulting layer, where a surface of the active layer fits the gate insulting layer; and
(S105) forming a source and drain on the active layer.

10. The method of claim 1, wherein each of the plurality of protrusions extends along a first direction, and the plurality of protrusions align in a sequence along a second direction perpendicular to the first direction.

11. The method of claim 2, wherein each of the plurality of protrusions straightly or windingly extends along the first direction.

12. The method of claim 3, wherein each of the plurality of protrusions is shaped as a semicircle or a shape close to a semicircle in a cross-sectional view along the second direction; the plurality of protrusions are equally-spaced along the second direction, and the coarse surface with the plurality of recesses along the second direction is wave-shaped in a cross sectional view.

13. The method of claim 3, wherein the plurality of protrusions in a cross sectional view is shaped as triangles; the plurality of protrusions are equally spaced and align in a sequence along the second direction, while the recesses on the coarse surface, aligning in a sequence along the second direction, are saw-shaped.

14. A liquid crystal display (LCD) panel comprising an array substrate, a color filter substrate, and liquid crystal layer therebetween, the array substrate comprising a glass substrate and a plurality of thin film transistors (TFTs) thereon, each TFT comprising: a gate formed on the glass substrate, a gate insulating layer covering the gate, an active layer formed on the gate insulating layer, a source on the active layer, and a drain on the active layer, wherein a gap is between the source and the drain in a first direction, an area of the active layer that matches the gap is a channel, and wherein a plurality of protrusions and recesses on a coarse surface of the gate insulating layer face the active layer, at least within the area corresponding to the channel, and the active layer fits with the gate insulting layer.

15. The LCD panel of claim 14, wherein each of the plurality of protrusions extends along a first direction, and the plurality of protrusions align in a sequence along a second direction perpendicular to the first direction.

16. The LCD panel of claim 15, wherein each of the plurality of protrusions straightly or windingly extends along the first direction.

17. The LCD panel of claim 16, wherein each of the plurality of protrusions is shaped as a semicircle or a shape close to a semicircle in a cross-sectional view along the second direction.

18. The LCD panel of claim 17, wherein the plurality of protrusions are equally-spaced along the second direction, and the coarse surface with the plurality of recesses along the second direction is wave-shaped in a cross sectional view.

19. The LCD panel of claim 16, wherein the plurality of protrusions in a cross sectional view is shaped as triangles.

20. The LCD panel of claim 19, wherein the plurality of protrusions are equally spaced and align in a sequence along the second direction, while the recesses on the coarse surface, aligning in a sequence along the second direction, are saw-shaped.
